(19) United States
(12) Patent Application Publication
(10) Pub. No.: US 2013/0037097 A1
(43) Pub. Date: Feb. 14, 2013

(54) PHOTOVOLTAIC MODULE WITH EDGE SEAL MASKING A BUS BAR

(71) Applicant: Pedro Gonzalez, Fremont, CA (US)

(72) Inventor: Pedro Gonzalez, Fremont, CA (US)

(21) Appl. No.: 13/564,274

(22) Filed: Aug. 1, 2012

Related U.S. Application Data
(60) Provisional application No. 61/521,431, filed on Aug. 9, 2011.

(51) Int. Cl. H01L 31/02; H01L 31/18

(52) U.S. Cl. 136/256; 438/73; 257/E31.117

(57) ABSTRACT

A photovoltaic module with at least one conductor extending along at least a portion of the peripheral edge of the module. A colored opaque edge seal extends over and in contact with at least a portion of the at least one conductor, to mask the appearance of the at least one conductor visible through a substrate. A method of forming the module is also described.

### CLAIM OF PRIORITY

This application claims priority under 35 U.S.C. §119(e) to U.S. Provisional. Patent Application Ser. No. 61/521,431 filed on Aug. 9, 2011, which is hereby incorporated by reference in its entirety.

### FIELD OF THE INVENTION

Embodiments of the invention relate to the field of photovoltaic (PV) module design and, more particularly, to PV modules and methods of manufacturing.

### BACKGROUND OF THE INVENTION

A PV module (also known as a solar module or a solar panel) is a device that converts the energy of sunlight directly into electricity by the photovoltaic effect. A PV module includes at least one PV cell, also known as a solar cell, for example, a crystalline silicon cell or a thin-film cell. The PV cells convert sunlight into electrical energy and are typically formed between the front and back covers of the PV module.

FIGS. 1A and 1B, respectively show a top down and cross-sectioned view of a portion of a PV module 100. A PV module can include a plurality of layers of various materials formed between the front 170 and back 150 covers of the PV module. The plurality of layers can include, for example, an active material layer. The active material layer is formed of one or more layers of semiconductor material such as amorphous silicon (a-Si), copper indium gallium diselenide (CIGS), cadmium telluride (CdTe), cadium sulfide (CdS) or any other suitable photoconversion material or combination of these materials. The front 170 and back 150 covers protect the plurality of layers of the PV cells from moisture penetration, physical damage, and other environmental hazards. The front 170 and back 150 covers can be made of a transparent material such as glass, to allow light to pass through to the active material layer of the cell. The PV module 100 may include one or more sub-modules, and each sub-module may include a plurality of PV cells which are electrically connected.

As shown in FIGS. 1A and 1B, conventional PV module 100 may have an edge seal material (for example, a polymeric compound such as polyisobutylene (PIB) in liquid hot melt form) applied around the periphery of a module 100 between an inner planar surface 155 of a back cover 150 and an inner planar surface 175 of a front cover 170. The edge seal 140 protects the interior of the PV module 100 from moisture and humidity penetration. The edge seal 140 is located adjacent to one or more bus bars 130 (also known as bus conductors, common conductors, photovoltaic ribbon, or buses) within module 100 which run along a peripheral edge 145 of the module and which extract the electricity generated by the at least one PV cell inside the PV module 100. Each bus bar 130 enables electrical connection of a module to additional electrical components outside the module 100. Each bus bar 130 has a thickness which partially or wholly extends between the back 150 and front 170 covers of the module 100. Since the one or more bus bars 130 are formed of a shiny metal material, e.g. aluminum, copper or other metal, they can be seen through the front cover 170 as producing a metallic appearance M and contrast with an otherwise uniform dark, e.g. black, appearance of the area 120 of the module 100 containing at least one PV cell, for example. The metallic appearance M of a bus bar 130 disrupts the uniform dark appearance of PV module 100 causing some customers to request a more uniform module appearance.

In an effort to make the appearance of module 100 more uniform across the entire front cover 170, a trim strip or black tape has been applied over one or more bus bars 130 to hide their metallic appearance. The trim strip is typically made of pigmented polyester or other inert polymer or fabric. This solution requires, however, additional material and additional manufacturing processing steps resulting in increased fabrication time and cost. Accordingly, there is needed a less costly, more efficient method of masking the metallic bus bars of a PV module to confer a uniform dark appearance to the PV module.

### BRIEF DESCRIPTION OF THE DRAWINGS

FIG. 1A illustrates a cut away top view of an existing PV module;

FIG. 1B illustrates a cross-sectioned view of the PV module of FIG. 1A taken along section A-A;

FIG. 2A illustrates a cut away top view of one embodiment of a PV module;

FIG. 2B illustrates a cross-sectioned view of the PV module of FIG. 2A taken along section B-B;

FIG. 3A illustrates a cut away top view of another embodiment of a PV module;

FIG. 3B illustrates a cross-sectioned view of the PV module of FIG. 3A taken along section C-C; and

FIG. 3C illustrates a cut away perspective view of the PV module of FIG. 3A.

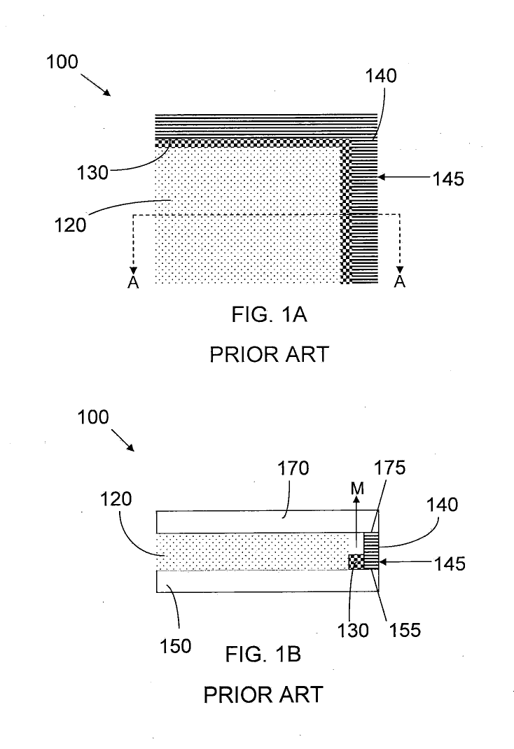

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed without departing from the spirit and scope of the invention.

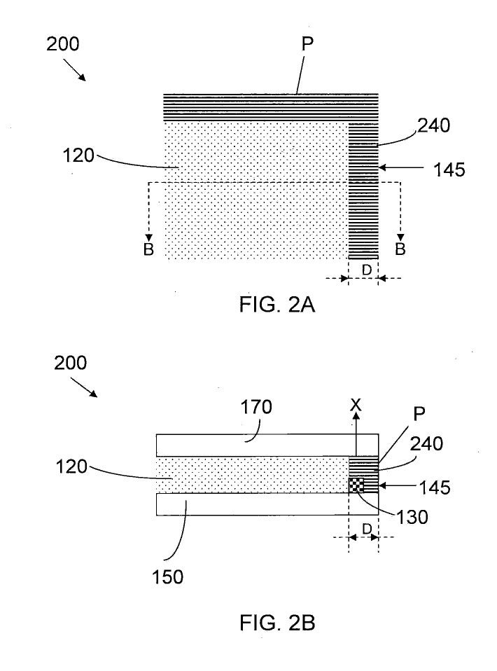

Referring now to the drawings, where like elements are designated by like reference numerals, FIG. 2A illustrates a cut away top view of a portion of a PV module 200 according to a disclosed embodiment. The edge seal 240 covers at least a portion of one or more bus bars 130, which would otherwise be visible through the front cover 170, to confer a substantially uniform dark, e.g. black, appearance X of the PV module preferred by customers. FIG. 2B illustrates a cross-sectioned view of FIG. 2A taken along section B-B.

During manufacturing, the plurality of PV cells (or at least one PV cell) formed in area 120 can be fabricated by any process known in the art. The plurality of PV cells and the edge seal 240 are sandwiched between the aligned front cover 170 and back cover 150 which define the top outer surface and the bottom outer surface, respectively, of PV module 200. Front cover 170 has a width and a length and back cover 150 has substantially the same width and length as the front cover 170. PV cells can be connected in series, parallel, or a combination thereof depending on the desired electrical output from PV module 200. The plurality of PV cells within a module 200 are connected in series by forming interconnects between adjacent cells, for example. Each bus bar 130 may be formed of tin, copper, aluminum, silver, gold, nickel, their alloys, or any other suitable conductive material or combination of such materials. Each bus bar 130 can function as one of a common positive and negative conductor, electrically connected to the first PV cells in the series or the last PV cells in the series, for example. Each bus bar 130 may pass through a hole provided in back cover 150 and be covered by a cord plate which allows external conductors to be electrically connected with a respective bus bar 130, or each bus bar 130 may extend outwardly of an edge of a module 200 between the front 170 and back 150 covers. The PV module 200 can include any suitable arrangement of series and parallel connections between the plurality of interior PV cells. If the PV module 200 is divided into two sub-modules, a first bus bar may serve as a common ground for both a first sub-module and a second sub-module. A second and third bus bar may serve as a positive bus bar for the first and second sub-modules, respectively.

Edge seal 240 protects PV module 200 from moisture intrusion, foreign substances, and other environmental hazards. Edge seal 240 can also serve as an adhesive, that bonds the front cover 170 to the back cover 150. Polyisobutylene (PIB), also known as butyl rubber, is a common edge seal material, but other examples of edge seals include opaque polymeric compounds. The edge seal material is usually dyed black, but may contain any colorant to match the overall color of the area 120 visible through the front cover 170.

The edge seal material that forms the edge seal 240 may be applied in liquid hot melt form, in tape form, or by any other known technology. The liquid hot melt edge seal material may cool to a solid state when the front cover 170 and the back cover 150 are combined during manufacturing. The cured edge seal material may be applied in liquid hot melt form during manufacturing using a hot melt process which may include a hot melt dispensing device, for example. The hot melt dispensing device may dispense the liquid edge seal material through an applicator attached to a hose, such that the liquid edge seal material is pumped from a dispensing pump connected to an edge seal material container. The liquid edge seal material may include a desiccant material. Additional details related to hot melt technology and use of an edge seal with a desiccant are provided, for example, in U.S. Patent Publ. No. 2009/0159117 to Ferri et al., the disclosure of which is incorporated by reference in its entirety herewith. The hot melt process allows manufacturers to vary the thickness of the edge seal.

In FIGS. 2A and 2B, one or more bus bars 130 abut the area 120 containing a plurality of PV cells (or at least one PV cell) and seal 240 contacts and completely covers at least a portion of one or more bus bars 130 otherwise visible through the front cover 170. Each bus bar 130 extends along at least a portion of a peripheral edge 145 of module 200. The edge seal 240 extends around at least a portion of the perimeter P of the PV module 200. The edge seal 240 also extends inwardly from a peripheral edge 145 of the module 200 a distance D (which also illustrates the width of the edge seal 240) of between about 7 mm and about 40 mm. The thickness of the edge seal 240 (measured between the interior surfaces of the front 170 and back 150 covers) may be between about 0.3 mm and about 1.0 mm. The width and thickness of the edge seal 240 are not limited however and, thus, the edge seal may have any width and thickness, depending on the specific characteristics of the PV module 200 and as long as the edge seal extends over at least a portion of one or more bus bars 130 visible through the front cover 170.

Although FIGS. 2A and 2B illustrate a back cover 150 adjacent to the area 120 containing the plurality of PV cells (or at least one PV cell), this is not limiting For example, additional layers may be inserted between the back cover 150 and the plurality of PV cells formed in area 120. In particular, an interlayer may be formed adjacent to the area 120. The interlayer may include a material selected from a group consisting of ethylene (EVA), polyvinyl butyral (PVB), polydimethylsiloxane (PDMS), butyl/PIB, polyolefin, thermoplastic polyurethane (TPU), polyurethane, epoxy, silicone and ionomer. The interlayer may serve as a moisture barrier, an electrical insulator between area 120 and the back cover 150, and/or a bonding agent that attaches the back cover 150 to the module 200 through a lamination process during manufacturing, for example.

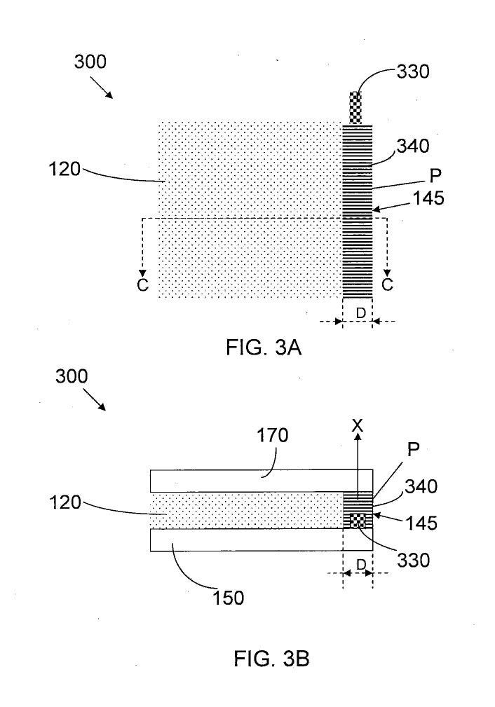

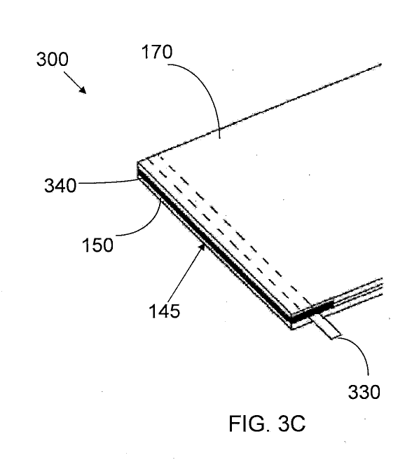

FIG. 3A illustrates a cut away top view of a portion of a PV module 300 according to a disclosed embodiment in which one or more bus bars 330 extend along at least a portion of a peripheral edge 145 of module 300 but do not abut the area 120. FIG. 3B shows a cross-sectioned view of FIG. 3A taken along section C-C and FIG. 3C illustrates a cut away perspective view of a portion of PV module 300. Seal 340 extends inwardly from a peripheral edge 145 of the module 300 a distance D. Because one or more bus bars 330 do not abut the area 120, seal 340 also extends between said area 120 and a bus bar 330.

The edge seal is used to conceal one or more bus bars of any PV module, e.g. crystalline, polycrystalline, CIGS, where the metallic appearance of a bus bar visible through the front cover 170 disrupts the uniform dark appearance of the PV module.

While embodiments have been described in detail, it should be readily understood that the invention is not limited to the disclosed embodiments. Rather the embodiments can be modified to incorporate any number of variations, alterations, substitutions or equivalent arrangements not heretofore described. Although certain features have been described with some embodiments of the edge seal, such features can be employed in other disclosed embodiments of the edge seal as well. Accordingly, the invention is not limited by the foregoing embodiments, but is only limited by the scope of the appended claims.

What is claimed as new and desired to be protected by Letters Patent of the United States is:

1. A photovoltaic module comprising:
a front cover;
a back cover aligned with the front cover;
an area containing at least one photovoltaic cell provided between the front cover and the back cover;
at least one conductor electrically connected to the at least one photovoltaic cell and extending along at least a portion of a peripheral edge of the module; and
an edge seal located over and in contact with at least a portion of the at least one conductor, to mask the appearance of the at least one conductor visible through the front cover.

2. The photovoltaic module of claim 1, wherein the at least one conductor abuts the area containing the at least one photovoltaic cell.

3. The photovoltaic module of claim 1, wherein the edge seal extends between the area containing the at least one photovoltaic cell and the at least one conductor.

4. The photovoltaic module of claim 1, wherein the edge seal extends around the perimeter of the module.

5. The photovoltaic module of claim 1, wherein the edge seal extends inwardly from the peripheral edge of the module for a distance of between about 7 mm and about 40 mm.

6. The photovoltaic module of claim 1, wherein the edge seal has a thickness of between about 0.3 mm and about 1.0 mm.

7. The photovoltaic module of claim 1, wherein the edge seal completely covers the at least one conductor.

8. The photovoltaic module of claim 1, wherein the edge seal is a cured liquid hot melt material.

9. The photovoltaic module of claim 1, wherein the edge seal is a tape material.

10. The photovoltaic module of claim 1, wherein the edge seal has a black color.

11. The photovoltaic module of claim 1, wherein the edge seal contains a colorant.

12. The photovoltaic module of claim 1, wherein the at least one conductor comprises one of tin, copper, aluminum, silver, gold, and their alloys.

13. The photovoltaic module of claim 1, wherein the edge seal comprises polyisobutylene.

14. The photovoltaic module of claim 1, wherein the edge seal comprises a desiccant material.

15. A method of manufacturing a photovoltaic module comprising the steps of:
forming an area containing at least one photovoltaic cell between a front cover and a back cover;
forming at least one conductor electrically connected to the at least one photovoltaic cell and extending along at least a portion of a peripheral edge of said module and between the front and back covers; and
applying an opaque edge seal around at least a portion of a peripheral edge of the module between the front and back covers and over at least a portion of the at least one conductor to mask an appearance of the at least one conductor which is otherwise visible through the front cover.

16. The method of claim 15, wherein the at least one conductor abuts the area containing the at least one photovoltaic cell.

17. The method of claim 15, wherein the edge seal is applied between the area containing the at least one photovoltaic cell and the at least one conductor.

18. The method of claim 15, wherein the edge seal is applied over the at least one conductor, to confer a substantially uniform color appearance of the photovoltaic module when viewed through said front cover.

19. The method of claim 15, wherein the edge seal extends inwardly from the peripheral edge of the module for a distance of between about 7 mm and about 40 mm.

20. The method of claim 15, wherein the opaque edge seal is applied in liquid hot melt form.

21. The method of claim 15, wherein the edge seal is applied in tape form.

22. The method of claim 15, wherein the edge seal extends around the perimeter of the module.
